(19) United States
(12) Patent Application Publication
(10) Pub. No.: US 2017/0323801 A1
(43) Pub. Date: Nov. 9, 2017

(54) METHOD OF GENERATING A POWER SEMICONDUCTOR MODULE

(71) Applicant: ABB Schweiz AG, Baden (CH)

(72) Inventors: Venkatesh Sivasubramaniam, Aesch (CH); David Guillon, Vorderthal (CH); Pauline Morin, Fislisbach (CH); Remi-Alain Guillemin, Nimes (FR); Samuel Hartmann, Staufen (CH)

(21) Appl. No.: 15/658,124

(22) Filed: Jul. 24, 2017

Related U.S. Application Data
(63) Continuation of application No. PCT/EP2015/074289, filed on Oct. 21, 2015.

(30) Foreign Application Priority Data
Jan. 23, 2015 (EP) 15152374.3

(51) Int. Cl. H01L 21/48; H01L 23/498; H01L 23/373

(52) U.S. Cl. CPC H01L 21/4853; H01L 23/3735; H01L 23/49811

(57) ABSTRACT

The present application relates to a method of generating a power semiconductor module including a carrier layer and a substrate having a terminal connection area, the method comprising: soldering the substrate to the carrier layer by forming a solder layer; wherein the solder layer is formed such, that a pre-defined cavity is provided in the solder layer adjacent to the substrate and located opposite to the terminal connection area; and welding a terminal to the terminal connection area of the substrate.

The present application provides a method of generating a power semiconductor module which is especially cost-saving to perform and allows a reliable generation of high quality modules.

### TECHNICAL FIELD

The present invention relates to power semiconductor modules. The present invention particularly raters to an improved method of generating a power semiconductor module.

### BACKGROUND ART

In production of high power semiconductor modules, traditionally soldering has been used as a conventional technique for fixing a terminal to a substrate. Even though soldering is appropriate tor some applications, high homologues temperature with its limited thermal conductivity of typical lead-rich or tin-rich solder materials limits the thermal cycling capabilities and thus may under circumstances require alternatives for specific applications. In fact, the soldered terminal is often prone to microstructural coarsening that may result in delamination.

Therefore, connecting terminals to the substrate is nowadays often realized by ultrasonic welding (USW) as this technique is reported to have improved reliability. In ultrasonic welding, a filler material (solder) may be omitted as the joining partner themselves constitutes to a benign joint. However, ultrasonic welding has as well potential to be improved. As an example, ultrasonic welding is prone to create conchoidal cracks on the ceramic substrate such as on an aluminum nitride (AlN) substrates. In fact, the ceramic is confronted with extreme tensile stresses that exceeds the breaking strength of the ceramic material itself, such as of AlN, wherein a stress concentration may occur at the edges of the terminal feet. This could be a possible reason for the crack formation.

Such conchoidal cracks are deleterious regarding the reliability of the power module, as typically it can cause isolation breakdown.

One approach to overcome this disadvantage is to adapt the parameters used, such as hardness of the material of the terminal, energy, pressure, amplitude, welding patterns, or feet thickness in order to reduce crack formation. Although the risks of cracks to occur can be reduced, such an approach, however, cannot completely avoid the risks at crack formation.

Therefore, further approaches are known in order to overcome the crack formation.

For example, it was tried to weld the terminal onto a ceramic having a higher breaking strength such as silicon nitride (SiN). However, silicon nitride is not compatible in all applications due to increase of thermal resistance (Rth) and it may also damage the stability of the baseplate bow.

A further approach was to provide and optimize an active metal brazing layer between the metallization and the ceramic (AMB). Such substrates however, mostly provide at least 10-20% increase of bill of materials (BOM) of the substrate.

Known from EP 2 219 220 A2 is further a structure being formed of a substrate which includes a radiator plate, an insulating layer on the radiator plate and a pad on the insulating layer. Further, a terminal is provided which is ultrasonic bonded to the pad. A thin metal layer formed of a soft metal or a highly slidable metal, such as gold, is located just below an edge of the terminal so as to be Interposed between the terminal and the pad. Gold coatings, however, are of high cost and are therefore not preferred.

In EP 0 886 894 A2 in FIG. 7 and FIG. 9A a semi-finished product for forming a power semiconductor module is disclosed.

Furthermore, in Y. Wang et al, “Challenges and trends of high power IGBT module packaging”, 2014 IEEE Conference and Expo Transportation. Electrification Asia-Pacific (ITEC Asia Pacific), 31. Aug. 2014 a generic high power IGBT Module is shown.

Kazumasa Kido et al. “Development of copper-copper bonding by ultrasonic welding for IGBT modules”, Electronic manufacturing (EMT). 2010 34^{th} IEEE/CPMT, 30. Nov. 2010 discloses a copper-copper bonding technique by ultrasonic welding for copper terminals of large current, high reliability GIST modules.

Moreover, in David Guillon, “Terminal coated with a Noble material in a power-electronics module optimized for ultrasonic welding”, IP.COM 24. Apr. 2015 a solution to reduce the stress undergoes by the ceramic substrate within the ultrasonic welding process is shown. The method is based on using a coaling material with low friction coefficient inducing a smooth rising of the temperature within the welding interface, furthermore the Coating material should have a high diffusion coefficient into copper material in order that the ultrasonic energy is absorbed within the welding interface and not directly transfer to the ceramic.

### DISCLOSURE OF INVENTION

It is an object of the present invention to provide a method tor generating a power semiconductor module which at least partly avoids one of the disadvantages of the prior art. It is particularly an object of the present invention to provide a method for generating a power semiconductor module which allows joining a terminal to a substrate by means of ultrasonic welding allowing a decreased risk of cracks to occur in the substrate.

These objects are at least partly solved by a method of generating a power semiconductor module according to independent claim I Advantageous embodiments are given in the dependent claims.

A method of generating a power semiconductor module comprises the steps of;

a) providing a carrier layer;

b) providing a substrate having a terminal connection area;

c) soldering the substrate to the carrier layer by forming a solder layer; wherein

d) the solder layer is formed such, that a pre-defined cavity is provided in the solder layer adjacent to the substrate and located opposite to the terminal connection area; and

e) welding a terminal to the terminal connection area of the substrate.

Such a method provides significant advantages with regard to the generation of a power semiconductor module and particularly to the step of welding a terminal to a substrate.

A power semiconductor module according to the present invention shall particularly mean an arrangement which Is based on one or more power semiconductor devices and which may preferably be used as a switch or rectifier in power electronics. Non-limiting examples for power semiconductor devices comprise inter alia gate turn-off thyristors, diodes, thyristors. Within the present invention, power semiconductor modules are especially those who comprise a substrate with a metallization which is joined to a die, i.e. the power semiconductor device, or a chip, respectively, with its front side and/or to a baseplate with its backside and wherein the substrate metallization is connected to a terminal foot.

In fact, the generated power semiconductor module generally comprises a substrate. The substrate comprises on its front side a plurality of circuit paths like generally known in the art. Such circuit paths may for example be formed from a metallization, such as from a copper metallization. The substrate metallization may be arranged on the particularly ceramic substrate main layer by physical or chemical deposition methods, for example, like it Is generally known in the art. Connected to the substrate metallization is at least one die or power semiconductor device, respectively, and further one or more terminals, or electrical connectors, respectively.

The substrate may generally be any substrate known in the art for power semiconductor modules. For example, the substrate may comprise an insulating material, such as a ceramic material. As non-limiting examples, the main layer of the substrate may be formed from aluminium nitride (AlN), silicon nitride (Si3N4) or aluminium oxide (Al2O3)

Further, in order to remove heat generated in the power semiconductor module, or especially in the power semiconductor device, the substrate may be connected to a carrier layer, such as to a baseplate. The basepiate is often formed from an ignoble metal, such as of copper, or AlSiC both of which may be coated with nickel, for example, and may act as a heat sink thereby effectively removing heat form the circuit paths. Further, the substrate may be coated with an ignoble metal, such as copper, at the area where the baseplate is joined to.

Generally, the substrate comprising its substrate metallization at its front side is connected to the carrier layer such as baseplate on its backside via a soldering process. Therefore, the arrangement comprising the substrate and the carrier layer comprises a solder layer between the substrate and the carrier layer.

In order to generate the power semiconductor module, further, a terminal is joined to the substrate via its substrate metallization via its terminal foot.

In detail, according to the present method and in order to generate a power semiconductor module, the method firstly comprises, according to step a), to provide a carrier layer. The carrier layer may particularly be a baseplate like described above which may be formed from copper, or AlSiC, and is generally well known to the person skilled in the art.

Further, according to step b) of the present method, the method further comprises the step of providing a substrate having a terminal connection area. The substrate is as well formed as generally known in the art and may comprise a main layer which is formed from an electrical insulating material, in particular a ceramic material, and may further comprise one or more metallizations on that main layer, exemplarily formed from copper. The substrate further comprises a terminal connection area. Such position is particularly located on a metallization of the substrate and thus at its front side. The terminal connection area thereby is that position at which the terminal, or the terminal foot, is fixed to the substrate and particularly has the same dimensions compared to the respective connection are of the terminal. In other words, the terminal connection area is that position or area of the substrate, which is intended to come into contact with a terminal or terminal foot when the latter is fixed to the substrate.

According to step c) of the present method, the method further comprises the step of soldering the substrate to the carrier layer by forming a solder layer. Soldering according to the present invention may thereby be generally a process in which two joining partners are joined together by a molten flowable soldering material which hardens after the soldering step and thus forms a stable connection. It is thus preferred that the soldering material has a lower melting point than the components to be soldered, or joined, respectively. The soldering material, or the solder, respectively, may thus be formed from a particularly low melting material as it is generally known in the art. As non-limiting examples, the soldering material may be formed of lead, or may preferably be formed from lead-free materials. However, generally any material such as meltable alloys which melt in an appropriate range such as below 360° C., preferable below 300° C., but as well in a range over 450° C. may be used.

Accordingly, the solder layer is located between the substrate and the carder layer and thus opposite to the terminal connection area. It comprises, or consists of, the hardened soldering material.

The soldering process may be used In a reducing atmosphere such as in formic gas, forming gas, i.e. a mixture of formic acid and nitrogen, hydrogen or ammonia. Especially the afore-named reducing gases can especially effectively prevent undesired effects to the solder layer during the soldering process and a mechanically stable and electrically and thermally conductive connection can be established without the use of any flux additional to the reducing atmosphere.

The usage of a soldering technique thereby allows an efficient and economic connection process thereby allowing a stable and reliable connection of the respective components, such as for example the baseplate and the substrate.

Regarding the solder layer and according to step d) of the present method, the solder layer is formed such, that a pre-defined cavity is provided in the solder layer adjacent to the substrate and located opposite to the terminal connection area. In other words, solder material is riot provided at each position of the solder layer, but certain locations of the solder layer are not filled with solder layer, thus forming cavities. These cavities are located opposite to the terminal connection area and thus facing the backside of the substrate and further located in direct vicinity of the substrate, i.e. adjacent to the substrate. In other words, the cavities are located such that defined areas of the substrate are not in contact with a solder material but in contrast thereto, are exposed with regard to the solder material. This exposed position thereby is opposite to the terminal connection area and thus In the sense of the present invention at least partly directly opposite to the terminal connection area.

The cavities are further pre-defined and their size as well as position is at least in a significant amount well defined before the soldering process starts. Therefore, the cavities are not formed by negative influences of the ultrasonic welding process, but are desired features of the solder layer. Accordingly, this step particularly comprises a measure for securing that one or more cavities, depending on the number of terminals, are formed in the solder layer at pre-defined positions and further having pre-defined dimensions. It may thereby be preferred that one cavity is provided for each terminal and thus opposite to each terminal connection area.

According to the further step e), the method comprises the step of welding a terminal to the terminal connection area of the substrate. In an especially preferred manner, an ultrasonic welding process is used.

This step of welding the terminal to the substrate, or substrate metallization, respectively, allows forming a joint between the terminal, or the terminal foot, respectively, and the substrate, or the substrate metallization, respectively, in a very advantageous manner.

When using a welding technique, such as ultrasonic welding, the joining partners plastically deform to form the joint. Referring to this, heat may be applied together with ultrasonic vibrations in order to form the connection as it is generally known in the art. As a non-limiting example in case both of the terminal foot and the substrate metallization are formed from copper, a stable and reliable copper-copper bond may be formed.

Welding allows forming a connection without additional material, such as solder material, and further provides a connection which is highly reliable and which has a good electrical conductivity.

Generally, as known from the prior art, however, by connecting a terminal to a substrate metallization especially using a welding technique, cracks may appear in the substrate especially in case the substrate comprises a ceramic material.

According to the present method and particularly due to the fact that according to step d) of the present method, the solder layer is formed such, that a pre-defined cavity is provided in the solder layer adjacent to the substrate and located opposite to the terminal connection area, such disadvantages may in a surprising manner be prevented.

In fact, the cavity which is provided in the solder layer as a ‘purposeful’ void area is interpreted to have a stress relaxation effect. Without being bound to the theory, the volume of the cavity is hypothesized to allow the ceramic material to locally bend in an elastic manner that helps in crack prevention. Therefore, providing a cavity in the solder layer effectively prevents formation of cracks in the substrate caused by the welding process, especially ultrasonic welding.

The generation of said one or more cavities, depending on the number of terminals to be connected, is further applicable without inferring significant additional cost. In detail, no or at least no significant process change is required as the cavity in the solder layer can be easily created with means provided during a production method of a power semiconductor module anyhow. For example a solder stop pattern may be used. Such a pattern may be provided e.g. on the carrier layer such as en the baseplate or substrate and may thus be provided from the respective supplier. Further, an aluminium wirebond spacer opposite to the foot area is generally possible to create a cavity such, that the wire bond hinders the solder from flowing to the location of the desired cavity. As aluminium is not wetted by most of the solders, a cavity may be formed.

Thus, the only measure which should be taken is to adapt the surface of the carrier layer or the substrate such, that the solder will not or less come into contact thereto.

Therefore, by using this method, the costs may be kept low, as no special grade ceramic is required for preventing cracks in the substrate, With regard to the BOM (bill of material), exemplarily 10 to 20% cost savings may be realized.

Further, as cracks may be securely avoided, the generated power semiconductor modules which are generated by a method like described above may be of high quality and have a high robustness.

This may be the truth even in case strong welding parameters are used, such as 300 Ws, or even more, such as 350 Ws, pressures of 2.5 bar or even more, such as 3 bar, as well as 90% amplitude.

To summarize, the present invention provides a method of generating a power semiconductor module which is especially cost-saving to perform and allows a reliable generation of high quality modules.

According to an embodiment, the cavity extends along the whole thickness of the solder layer. This embodiment allows an especially effective reduction or prevention of cracks in the substrate. Furthermore, such a cavity is especially easy to prepare as no special measures have to be taken in order to get a defined heights of the cavity. A cavity extending along the whole thickness of the solder layer shall thereby mean a cavity which extends from the carrier layer such as from the baseplate to the substrate, particularly in a direction perpendicular to the surface of the carrier layer and the substrate.

According to a further embodiment, the cavity has an expansion in a plane parallel to the plane of the solder layer lying in the range of ≧50% to ≦200%, such as ≧70% to ≦130%, for example ≧90% to ≦110%. in particular 100%, compared to the parallel expansion of the terminal connection area. Unexpectedly, already a cavity having such dimensions is enough in order to get a significant prevention of crack formation without negatively influencing the stability and robustness of the whole generated arrangement. The plane parallel to the plane of the solder layer shall thereby mean a plane which is parallel to the surface of the substrate and the baseplate and thus is arranged between them. It may be defined by two rectangular directions having a right angle to the thickness of the solder layer. In other words, such plane may be parallel to the connection surface of the terminal and of the substrate, or the terminal connection area, respectively. A typical respective size, or extension, respectively, of a terminal foot may lie in the range of 16 mm². Therefore already an exemplary range of ≧50% to ≦200% of 16 mm² of the respective extension of the cavity may be sufficient.

However, exemplary, the cavities may have respective expansions which may be bigger, such as in the range of 20 mm²or 36 mm².

Due to the fact that the cavities have comparably small dimensions, the stability of the module is not significantly decreased. As exemplary values, the pre-defined cavities may form an amount of approximately less than 5% of the solder. Thus, it becomes clear that the stability is not significantly decreased and the risk of yield loss due to voiding can be kept at minimum.

According to a further embodiment, the cavity is defined and formed by using a coating formed on at least one of the carrier layer and the substrate, in other words, the coating shall define the location and size of the coating by applying the latter to the substrate or the basepiate which in turn leads to the formation of a cavity in the solder layer at the respective position. Such a coating may for example be a material known as solder mask or solder stop mask and may be formed as a thin lacquer-like layer of polymer material. Non-limiting examples comprise inter alia epoxy liquids, liquid photoimageable soldermasks (LPI) or non photoimageable soldermasks. The advantage of such a material is inter sib that these materials are commercially available with low prices, allowing the method according to the invention to be realized in a cost-saving manner. Apart from that, such materials are under circumstances anyhow used in a process of forming a power semiconductor module in order to mask the baseplate before soldering the substrate thereto. Therefore, by simply changing the geometry of applied solder stop material such that the respective positions opposite to the terminal connection area are comprised, the cavities may be formed in an easy and well-defined manner.

The applications of such materials may thereby be realized by using different processes, each of which allowing to form a defined cavity at defined positions. Examples comprise silk screen or stencil printing.

According to a further embodiment, the substrate comprises aluminum nitride (AlN). Especially a substrate comprising aluminum nitride combines a plurality of advantageous features, such as of sustaining high voltages, high electrical insulation strength, good thermal behavior and low costs. Therefore, especially aluminum nitride is often used as a substrate in the field of power semiconductor modules which, however, is often especially susceptible for crack formation due to a welding process. According to the invention, even when using aluminum nitride, crack formation may be significantly reduced.

With regard to further advantages or features of the method according to the invention it is referred to the semi-finished product, the figures as well as to the description of the figures.

A semi-finished product for forming a power semiconductor module comprises a carrier layer and a substrate, wherein the substrate is connected to the carrier layer by a solder layer, wherein the substrate comprises a terminal connection area for connecting a terminal thereto, the terminal connection area being located opposite to the solder layer, wherein a cavity is provided in the solder layer located adjacent to the substrate and opposite to the terminal connection area. It may further be provided that the semi-finished product consists of the afore-mentioned parts.

Such a semi-finished product allows reliably generating a power semiconductor module having a high quality.

In fact, the semi-finished product is an arrangement which comprises or consists of a carrier layer, such as a baseplate, a substrate and a solder layer connecting the carrier layer and the substrate and thus being located between the substrate and the carrier layer. Further, a defined cavity is provided in the solder layer opposite to the terminal connection area.

Such a semi-finished product allows welding the terminal to the substrate, or substrate metallization, respectively, with no or at least a significantly reduced risk of cracks to appear in the ceramic material of the substrate.

In fact, it may effectively be prevented that cracks appear when welding a terminal to the terminal connection area, especially by using ultrasonic welding. Therefore, the semi-finished product comprises the one or more cavities Opposite to the one or mom terminal connection areas, particularly one cavity for each terminal connection area, in a state when the terminal is not welded to the substrate and thus before the welding process. The semi-finished product may thus comprise a terminal, which may contact the substrate at the terminal connection area, but which is not connected and thus not welded to the substrate. The terminal may thus be present at the terminal connection area of the substrate loosely.

The substrate comprises aluminum nitride (AlN). Especially such a substrate combines a plurality of advantageous features of sustaining high voltages, high electrical insulation strength, good thermal behavior and km costs. Therefore, especially aluminum nitride is often used as a substrate in the field of power semiconductor modules which, however, is often especially susceptible for crack formation due to a welding process. However, even when using aluminum nitride, according to the present invention, crack formation may be significantly reduced.

It may be preferred that the solder layer comprises a material selected from the group consisting of, lead (Pb), tin (Sn), silver (Ag), antimony (Sb), gold (Au), germanium (Ge), indium (In), bismuth (Bi), copper (Cu) or a mixture or an alloy including at least one of the afore-mentioned materials, such as in a non-limiting example SnPb, SnSb, AuSn, AuGe, In, InPb, InAg, InSn, BiSn, SnAg, PbSnAg, PbInAg, or SnAgCu. Especially the afore-mentioned compounds may secure that the material may melt under appropriate conditions and may further allow good wetting properties. As a result, an especially reliable solder connection may be formed according to this embodiment.

The carrier layer may particularly be a baseplate like described above which may be formed from copper (Cu), or Aluminum Silicon Carbide (AlSiC), and is generally well known to the person skilled in the art.

With regard to further advantages or features of the semi-finished product it is referred to the method, the figures as well as to the description of the figures.

### BRIEF DESCRIPTION OF DRAWINGS

These and other aspects of the invention will be apparent from and elucidated with reference to the embodiments described hereinafter.

In the drawings:

FIG. 1 shows an exemplary embodiment of a semi-finished product;

FIG. 2 shows a top view onto a solder layer as part of a semifinished product having pre-defined cavities.

### DETAILED DESCRIPTION OF THE INVENTION

Reference will now be made in detail to an exemplary embodiment, which is illustrated in the figures. This example is provided by way of explanation and is not meant as a limitation. It is intended that the present disclosure includes further modifications end variations.

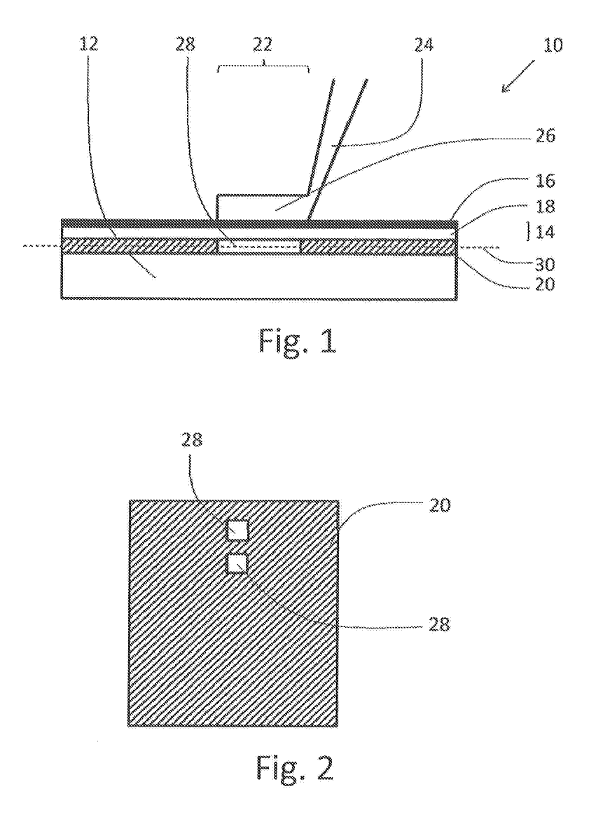

FIG. 1 shows an example of a semi-finished product 10. The semi-finished product 10 may be used for forming a power semiconductor module. It comprises a carrier layer 12 and a substrate 14.

The carrier layer 12 may particularly be a baseplate and may be formed from copper, or Aluminium Silicon Carbide, and is generally well known to the person skilled in the art.

The substrate 14 comprises on its front side a plurality of circuit paths like generally known in the art and not especially visualized in the figure. Such circuit paths may for example be formed from a metallization 16, such as from a copper metallization, which is formed on a substrate main layer 18. The substrate 14 may generally be any substrate known In the art for power semiconductor modules. For example, the substrate 14 may comprise an insulating material, such as a ceramic material, particularly forming the main layer 18. As non-limiting examples, the main layer 18 of the substrate may be formed from aluminium nitride (AlN), silicon nitride (Si3N4) or aluminium oxide (Al2O3).

The substrate 14 is further connected to the corner layer 12 by a solder layer 20. It may be preferred that the soldering material which forms the solder layer 20 is chosen from the group consisting of, lead (Pb), tin (Sn), silver (Ag), antimony (Sb), gold (Au), germanium (Ge), indium (In), bismuth (Bi), copper (Cu) or a mixture or an alloy including at least one of the afore-mentioned compounds, such as in a non-limiting example SnPb, SnSb, AuSn, AuGe, In, InPb, InAg, InSn, BiSn, SnAg, PbSnAg, PbInAg, or SnAgCu.

Further, the substrate 14 comprises a terminal connection area 22 for connecting a terminal 24 thereto. Like can be seen in FIG. 1, the terminal connection area 22 is located opposite to the solder layer 20 and is particularly a part of the substrate metallization 16. It can further be seen, that the terminal 24 is located at the terminal connection area 22. However, in case such a terminal 24 is present, the latter is not welded to the substrate 16 but is loosely on the terminal connection area 22.

The terminal 24 may contact the substrate metallization 16 by means of a terminal foot 26. The area of the terminal foot 26 coming in contact to the substrate 14, or the substrate metallization 16, respectively, corresponds to the area of the terminal connection area 22.

The semi-finished product 10 further comprises a cavity 28 in the solder layer 20. It can be seen that the cavity 28 is located adjacent to the substrate 14 and opposite to the terminal connection area 22.

If is shown that the cavity 26 extends along the whole thickness of the solder layer 20. Further, the cavity has an expansion in a plane 30 parallel to the solder layer 20 lying in the range of ≧50% to ≦200% compared to the parallel if expansion of the terminal connection area 22 and thus of the terminal foot 26. According to FIG. 1, the expansion of the cavity 28 is slightly smaller compared to the terminal connection area 22.

Such a semi-finished product 10 may be formed from the following steps:

a) providing the carrier layer 12;

b) providing the substrate 14 with its terminal connection area 22; and

c) soldering the substrate 14 to the carrier layer 12 by forming a solder layer 20; wherein

d) the solder layer 20 is formed such, that the cavity 28 is provided adjacent to the substrate 14 and located opposite to the terminal connection area 20.

In order to generate the power semiconductor module 10, the following step e) may be comprised and may particularly be realized after step d): welding a terminal 24 to the terminal connection area 22 of the substrate 14, in particular by means of ultrasonic welding.

In order to generate the power semiconductor module 10, further steps may be included such as joining dies to the metallization 16. The further steps, however are well known in the art and are thus not described in detail.

FIG. 2 shows a top view onto a solder layer 20. It can clearly be seen that the solder layer 20 comprises cavities 28, which cavities are present, when the solder layer 20 is present adjacent to the substrate 14, opposite to respective terminal connection areas 22.

While the invention has been illustrated and described in detail in the drawings and foregoing description, such illustration and description are to be considered illustrative or exemplary and not restrictive; the invention is not limited to the disclosed embodiments. Other variations to be disclosed embodiments can be understood and effected by those skilled in the art in practicing the claimed invention, from a study of the drawings, the disclosure, and the appended claims. in the claims, the word “comprising” does not exclude other elements or steps, and the indefinite article a or “an” does not exclude a plurality. The mere fact that certain measures are recited in mutually different dependent claims does not indicate that a combination of these measures cannot be used to advantage. Any reference signs in the claims should not be construed as limiting scope.

### REFERENCE SIGNS LIST

10 semi-finished product
12 carrier layer
14 substrate
16 metallization
18 main layer
20 solder layer
22 terminal connection area
24 terminal
26 terminal loot
28 cavity
30 plane

1. A method of generating a power semiconductor module including a carrier layer and a substrate having a terminal connection area, the method comprising:
soldering the substrate to the carrier layer by forming a solder layer; wherein
the solder layer is formed such, that a pre-defined cavity is provided in the solder layer adjacent to the substrate and located opposite to the terminal connection area; and
welding a terminal to the terminal connection area of the substrate.

2. The method according to claim 1, wherein the cavity extends along the whole thickness of the solder layer.

3. The method according to claim 1, wherein the cavity has an expansion in a plane parallel to the plane of the solder layer lying in the range of ≧50% to ≦200% compared to the parallel expansion of the terminal connection area.

4. The method according to claim 1, wherein the cavity is defined by using a coating formed on at least one of the carrier layer and the substrate.

5. The method according to claim 1, wherein the substrate comprises aluminum nitride.

6. The method according to claim 1, wherein the terminal is welded to the substrate by means-of ultrasonic welding.

7. The method according to claim 2, wherein the cavity has an expansion in a plane parallel to the plane of the solder layer lying in the range of ≧50% to ≦200% compared to the parallel expansion of the terminal connection area.

8. The method according to claim 2, wherein the cavity is defined by using a coating formed on at least one of the carrier layer and the substrate.

9. The method according to claim 3, wherein the cavity is defined by using a coating formed on at least one of the carrier layer and the substrate.

10. The method according to claim 4, wherein the substrate comprises aluminum nitride.

11. The method according to claim 3, wherein the substrate comprises aluminum nitride.

12. The method according to claim 2, wherein the substrate comprises aluminum nitride.

13. The method according to claim 5, wherein the terminal is welded to the substrate-by ultrasonic welding.

14. The method according to claim 4, wherein the terminal is welded to the substrate-by ultrasonic welding.

15. The method according to claim 3, wherein the terminal is welded to the substrate by ultrasonic welding.

16. The method according to claim 2, wherein the terminal is welded to the substrate by ultrasonic welding.

17. The method of claim 1, wherein the cavity extends along the whole thickness of the solder layer;
wherein the cavity has an expansion in a plane parallel to the plane of the solder layer lying in the range of ≧50% to ≦200% compared to the parallel expansion of the terminal connection area
wherein the cavity is defined by using a coating formed on at least one of the carrier layer and the substrate;
wherein the substrate comprises aluminum nitride; and
wherein the terminal is welded to the substrate by ultrasonic welding.

18. The method of claim 1, wherein the cavity extends along the whole thickness of the solder layer;
wherein the cavity has an expansion in a plane parallel to the plane of the solder layer lying in the range of ≧50% to ≦200% compared to the parallel expansion of the terminal connection area
wherein the cavity is defined by using a coating formed on at least one of the carrier layer and the substrate; and
wherein the substrate comprises aluminum nitride.

19. The method of claim 1, wherein the cavity has an expansion in a plane parallel to the plane of the solder layer lying in the range of ≧50% to ≦200% compared to the parallel expansion of the terminal connection area
wherein the cavity is defined by using a coating formed on at least one of the carrier layer and the substrate; and
wherein the terminal is welded to the substrate by ultrasonic welding.

20. The method of claim 1, wherein the cavity extends along the whole thickness of the solder layer;
wherein the cavity is defined by using a coating formed on at least one of the carrier layer and the substrate;
wherein the substrate comprises aluminum nitride; and
wherein the terminal is welded to the substrate by ultrasonic welding.
